(19) United States
(12) Patent Application Publication
(10) Pub. No.: US 2019/0122994 A1
(43) Pub. Date: Apr. 25, 2019

(54) SEMICONDUCTOR PACKAGE

(71) Applicant: SAMSUNG ELECTRO-MECHANICS CO., LTD., Suwon-si (KR)

(72) Inventors: Yong Koon LEE, Suwon-si (KR); Jin Gu KIM, Suwon-si (KR); Jin Su KIM, Suwon-si (KR)

(21) Appl. No.: 15/950,000

(22) Filed: Apr. 10, 2018

(30) Foreign Application Priority Data
Oct. 20, 2017 (KR) 10-2017-0136475

(51) Int. Cl. H01L 23/552; H01L 23/31; H01L 23/538; H01L 23/00; H01L 21/48; H01L 21/56

(52) U.S. Cl. CPC H01L 23/552; H01L 23/3114; H01L 23/3128; H01L 23/5383; H01L 23/5386; H01L 23/5389; H01L 2924/3025; H01L 24/19; H01L 21/4857; H01L 21/4853; H01L 21/565; H01L 2224/214; H01L 24/20

(57) ABSTRACT

A semiconductor package includes a semiconductor chip having an active surface having connection pads disposed thereon and an inactive surface opposing the active surface; an encapsulant encapsulating at least a portion of the semiconductor chip; and a connection member including an insulating layer disposed on the active surface of the semiconductor chip, a signal pattern disposed in the insulating layer, first ground patterns disposed to be spaced apart from the signal pattern on both sides of the signal pattern, second ground patterns disposed to be spaced apart from the signal pattern in an upper portion and a lower portion of the signal pattern, and line vias connecting the first ground patterns and the second ground patterns to each other and having a line shape.

### CROSS-REFERENCE TO RELATED APPLICATION

This application claims benefit of priority to Korean Patent Application No. 10-2017-0136475 filed on Oct. 20, 2017 in the Korean Intellectual Property Office, the disclosure of which is incorporated herein by reference in its entirety.

### BACKGROUND

### 1. Field

The present disclosure relates to a semiconductor package.

### 2. Description of Related Art

Semiconductor packages have been continuously required to be thinned and lightened in terms of a shape thereof, and have been required to be implemented in a system in package (SiP) form requiring increased complexity and multifunctionality in terms of a function. In accordance with such a development trend, a fan-out wafer level package (FOWLP) has recently been prominent, and attempts to satisfy requirements of semiconductor packaging by applying several techniques to the FOWLP have been conducted.

In particular, with the commercialization of 5^{th} generation wireless systems (5G) and Internet of Things (IoT), increasing amounts of data need to be processed and communications between semiconductors or between devices in a high frequency region is required. To this end, a redistribution layer and substrates of a semiconductor package, such as a main board, and the like, require implementation of a circuit having a finer pitch than a conventional circuit and reliable signal transmission characteristics. Accordingly, there is demand for a structure for electrical shielding between adjacent signal lines in the semiconductor package.

### SUMMARY

An aspect of the present disclosure may provide a semiconductor package that enhances electrical shielding between adjacent signal lines to remove mutual interference.

According to an aspect of the present disclosure, in a connection member for redistributing connection pads of a semiconductor chip, ground patterns may be disposed to surround a signal line.

According to an aspect of the present disclosure, a semiconductor package may include a semiconductor chip having an active surface having connection pads disposed thereon and an inactive surface opposing the active surface; an encapsulant encapsulating at least a portion of the semiconductor chip; and a connection member including an insulating layer disposed on the active surface of the semiconductor chip, a signal pattern disposed in the insulating layer, first ground patterns disposed to be spaced apart from the signal pattern on both sides of the signal pattern, second ground patterns disposed to be spaced apart from the signal pattern in an upper portion and a lower portion of the signal pattern, and line vias connecting the first ground patterns and the second ground patterns to each other and having a line shape.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a schematic block diagram illustrating an embodiment of an electronic device system;

FIG. 2 is a schematic perspective view illustrating an embodiment of an electronic device, an inset in FIG. 2 shows an enlarged view of a region A of the electronic device;

FIGS. 3A1, 3A2, 3A3, 3A4, 3B1, and 3B2 are schematic cross-sectional views illustrating states of a fan-in semiconductor package before (FIGS. 3A1, 3A2, and 3B1) and after (FIGS. 3A3, 3A4, and 3B2) being packaged;

FIG. 4 are schematic cross-sectional views illustrating packaging processes for manufacturing a fan-in semiconductor package;

FIG. 5 is a schematic cross-sectional view illustrating a case in which a fan-in semiconductor package is mounted on an interposer substrate mounted on a main board of an electronic device;

FIG. 6 is a schematic cross-sectional view illustrating a case in which a fan-in semiconductor package is embedded in an interposer substrate mounted on a main board of an electronic device;

FIG. 7 is a schematic cross-sectional view illustrating a fan-out semiconductor package;

FIG. 8 is a schematic cross-sectional view illustrating a case in which a fan-out semiconductor package is mounted on a main board of an electronic device;

FIGS. 9A through 9C are schematic cross-sectional views illustrating an embodiment of a fan-out semiconductor package;

FIG. 10 is a schematic plan view taken along line I-I′ of the fan-out semiconductor package of FIG. 9A;

FIG. 11 is a schematic perspective view illustrating an embodiment of various signal patterns and ground patterns included in a connection member of the fan-out semiconductor package of FIG. 9A;

FIGS. 12A through 12E are schematic cross-sectional views illustrating an embodiment of a processor for forming a connection member of the fan-out semiconductor package of FIG. 9A;

FIG. 13 is a schematic cross-sectional view illustrating another embodiment of a fan-out semiconductor package; and

FIG. 14 is a schematic cross-sectional view illustrating another embodiment of a fan-out semiconductor package.

### DETAILED DESCRIPTION

Hereinafter, exemplary embodiments in the present disclosure will be described with reference to the accompanying drawings. In the accompanying drawings, shapes, sizes, and the like, of components may be exaggerated or shortened for clarity.

Electronic Device

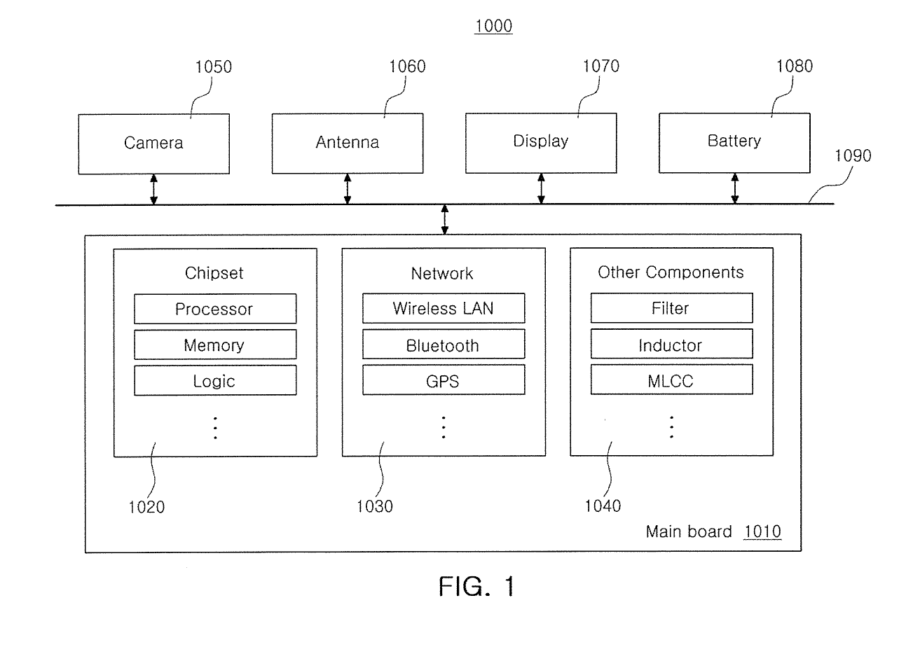

FIG. 1 is a schematic block diagram illustrating an embodiment of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components maybe connected to others to be described below through signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital converter (ADC), an application-specific integrated circuit (ASIC), or the like. However, the chip related components 1020 are not limited thereto, and may also include other types of chip-related components. In addition, the chip related components 1020 may be combined with each other.

The network related components 1030 may include protocols such as wireless local area network (LAN) including wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access +(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), and the like. However, other components 1040 are not limited thereto, and may also include passive components used for various other purposes, and the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. These other components may include, for example, a camera 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, and may also include other components used for various purposes depending on a type of electronic device 1000, or the like.

The electronic device 1000 may be a smartphone, smart speakers, a personal digital assistant (PDA), a digital video camera, a digital still camera, a network system, a computer, a monitor, a tablet personal computer (PC), a laptop PC, a netbook PC, a television, a video game machine, a smartwatch, an automotive component, or the like. However, the electronic device 1000 is not limited thereto, and may be any other electronic device processing data.

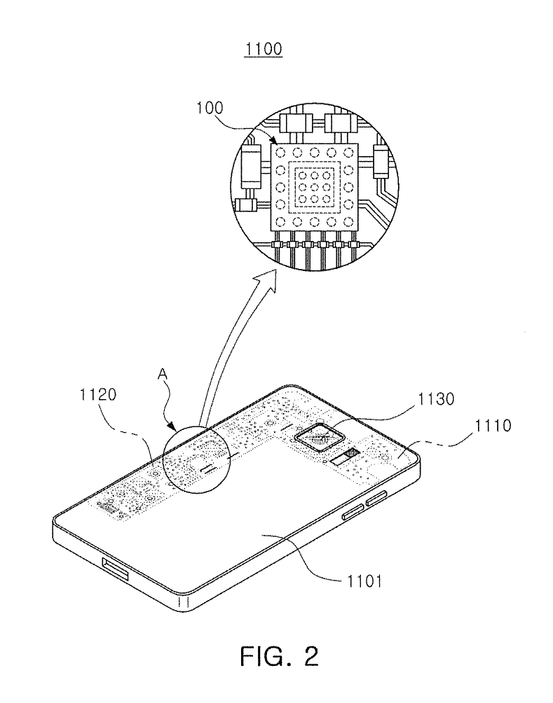

FIG. 2 is a schematic perspective view illustrating an example of an electronic device.

Referring to FIG. 2, a semiconductor package may be used for various purposes in the various electronic devices 1000 as described above. For example, a motherboard 1110 may be accommodated in a body 1101 of a smartphone 1100, and various components 1120 may be physically or electrically connected to the motherboard 1110. In addition, other components that may or may not be physically or electrically connected to the mainboard 1010, such as a camera 1130, may be accommodated in the body 1101. Some of the electronic components 1120 may be the chip related components, and the semiconductor package 100 may be, for example, an application processor among the chip related components, but is not limited thereto. The electronic device is not necessarily limited to the smartphone 1100, and may be other electronic devices as described above.

Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, and may be packaged and used in an electronic device, or the like, in a packaged state.

Here, semiconductor packaging is required, due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor chip and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-in Semiconductor Package

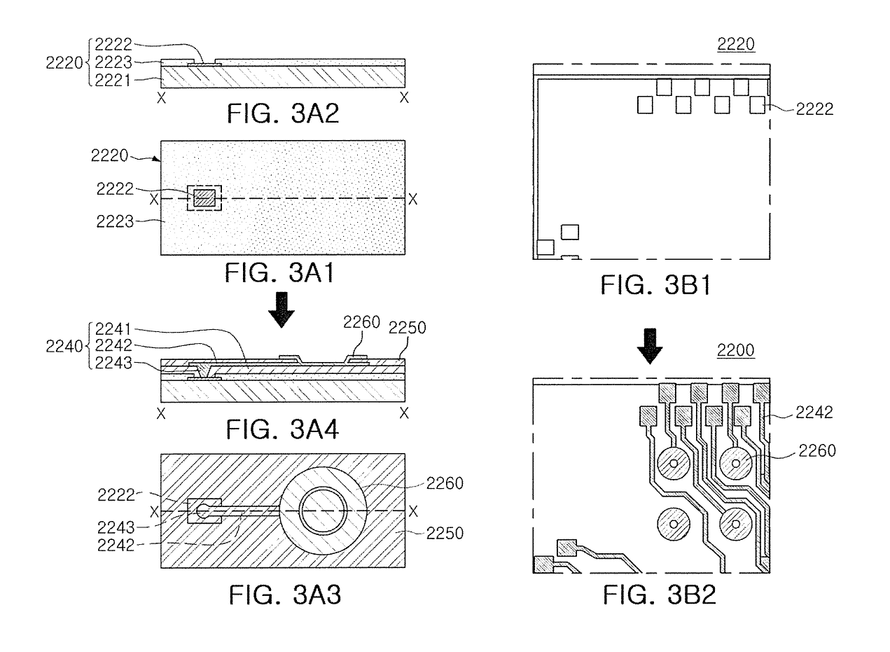

FIGS. 3A1, 3A2, 3A3, 3A4, 3B1, and 3B2 are schematic cross-sectional views illustrating states of a fan-in semiconductor package before (FIGS. 3A1, 3A2, and 3B1) and after (FIGS. 3A3, 3A4, and 3B2) being packaged.

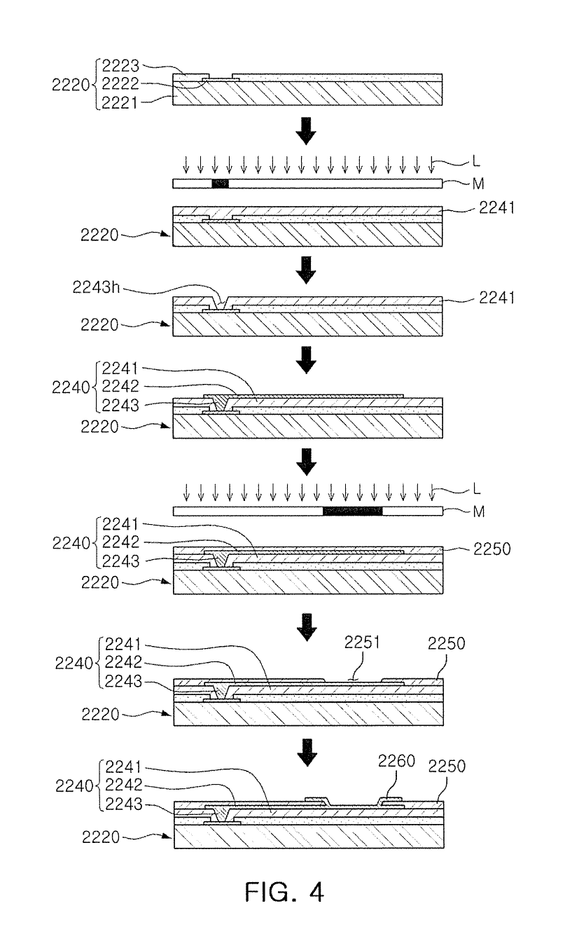

FIG. 4 is a schematic cross-sectional view illustrating a packaging process of a fan-in semiconductor package.

Referring to the drawings in FIGS. 3A1, 3A2, 3A3, 3A4, 3B1, 3B2, and 4, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide film, a nitride film, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, depending on a size of the semiconductor chip 2220, a connection member 2240 may be formed on the semiconductor chip 2220 in order to redistribute the connection pads 2222. The connection member 2240 may be formed by forming an insulating layer 2241 on the semiconductor chip 2220 using an insulating material such as photoimagable dielectric (PID) resin, forming via holes 2243h opening the connection pads 2222 through photolithography using a mask M (with the black-colored portion indicating a mask opening) and light L of an appropriate wavelength, and then forming wiring patterns 2242 and vias 2243. Then, a passivation layer 2250 protecting the connection member 2240 may be formed, an opening 2251 may be formed through photolithography using a mask M (with the black-colored portion indicating a mask opening, and mask M may be a mask of the same type as or different type than the mask M for the via holes 2243h) and light L of an appropriate wavelength which may be the same or different than the light used for forming via holes 2243h, and an underbump metal layer 2260, or the like, may be formed. That is, a fan-in semiconductor package 2200 including, for example, the semiconductor chip 2220, the connection member 2240, the passivation layer 2250, and the under-bump metal layer 2260 may be manufactured through a series of processes.

As described above, the fan-in semiconductor package may have a package form in which all of the connection pads, for example, input/output (I/O) terminals, of the semiconductor chip, are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the mainboard of the electronic device. The reason is that even in a case in which a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in semiconductor package on the mainboard of the electronic device.

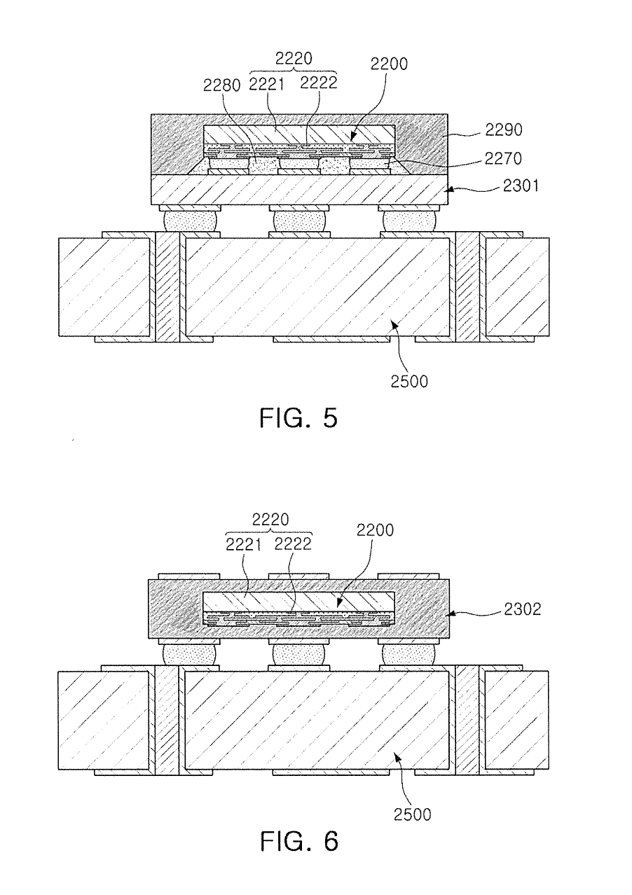

FIG. 5 is a schematic cross-sectional view illustrating a case in which a fan-in semiconductor package is mounted on an interposer substrate and is ultimately mounted on a mainboard of an electronic device.

FIG. 6 is a schematic cross-sectional view illustrating a case in which a fan-in semiconductor package is embedded in an interposer substrate and is ultimately mounted on a mainboard of an electronic device.

Referring to FIGS. 5 and 6, in a fan-in semiconductor package 2200, connection pads 2222, that is, I/O terminals, of a semiconductor chip 2220 may be redistributed through an interposer substrate 2301, and the fan-in semiconductor package 2200 may be ultimately mounted on a mainboard 2500 of an electronic device in a state in which it is mounted on the interposer substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate interposer substrate 2302, connection pads 2222, that is, I/O terminals, of the semiconductor chip 2220 may be redistributed by the interposer substrate 2302 in a state in which the fan-in semiconductor package 2200 is embedded in the interposer substrate 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package may be mounted on the separate interposer substrate and be then mounted on the mainboard of the electronic device through a packaging process or may be mounted and used on the mainboard of the electronic device in a state in which it is embedded in the interposer substrate.

Fan-Out Semiconductor Package

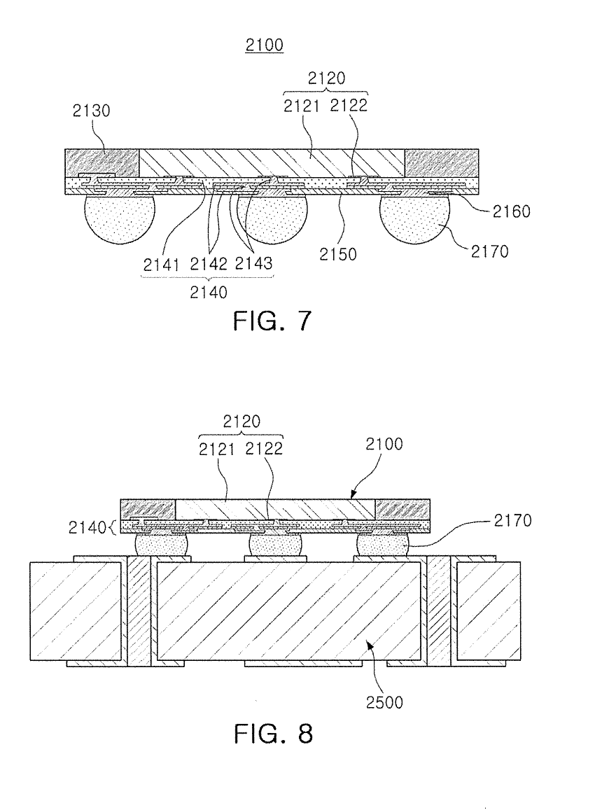

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2202 may further be formed on the connection member 2140, and an underbump metal layer 2160 may further be formed in openings of the passivation layer 2202. Solder balls 2170 may further be formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in a case in which a size of the semiconductor chip is decreased, a standardized ball layout may be used in the fan-out semiconductor package as it is, such that the fan-out semiconductor package may be mounted on the mainboard of the electronic device without using a separate interposer substrate, as described below.

FIG. 8 is a schematic cross-sectional view illustrating a case in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate interposer substrate, or the like.

As described above, since the fan-out semiconductor package may be mounted on the mainboard of the electronic device without using the separate interposer substrate, the fan-out semiconductor package may be implemented at a thickness lower than that of the fan-in semiconductor package using the interposer substrate. Therefore, the fan-out semiconductor package may be miniaturized and thinned. In addition, the fan-out semiconductor package has excellent thermal characteristics and electrical characteristics, such that it is particularly appropriate for a mobile product. Therefore, the fan-out semiconductor package may be implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor chip on the mainboard of the electronic device, or the like, as described above, and protecting the semiconductor chip from external impacts, and is a concept different from that of a printed circuit board (PCB) such as an interposer substrate, or the like, having a scale, a purpose, and the like, different from those of the fan-out semiconductor package, and having the fan-in semiconductor package embedded therein.

In a connection member for redistributing connection pads of a semiconductor chip, a fan-out semiconductor package that enhances an electrical shielding between adjacent signal lines to remove mutual interference will hereinafter be described with reference to the drawings.

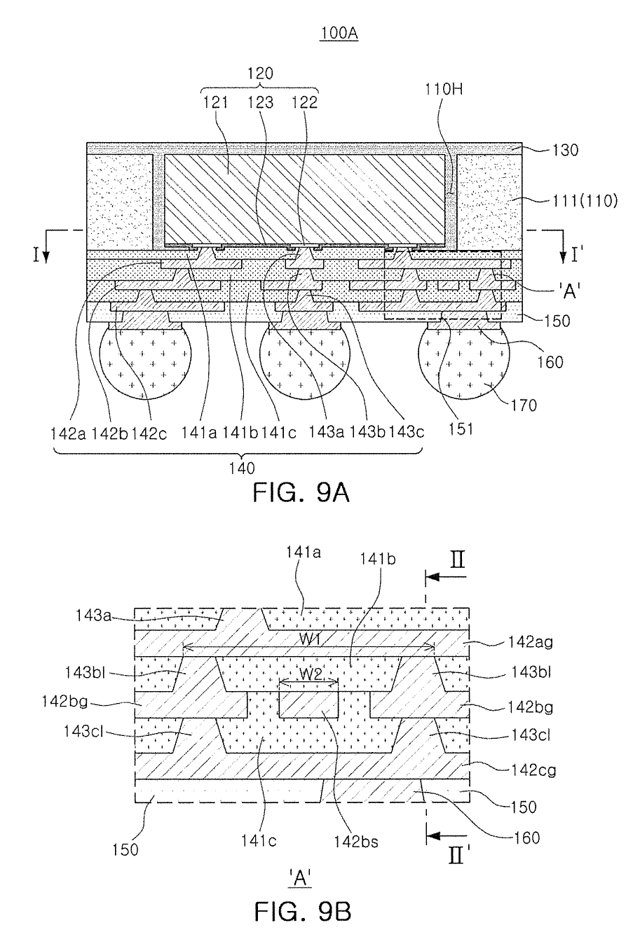

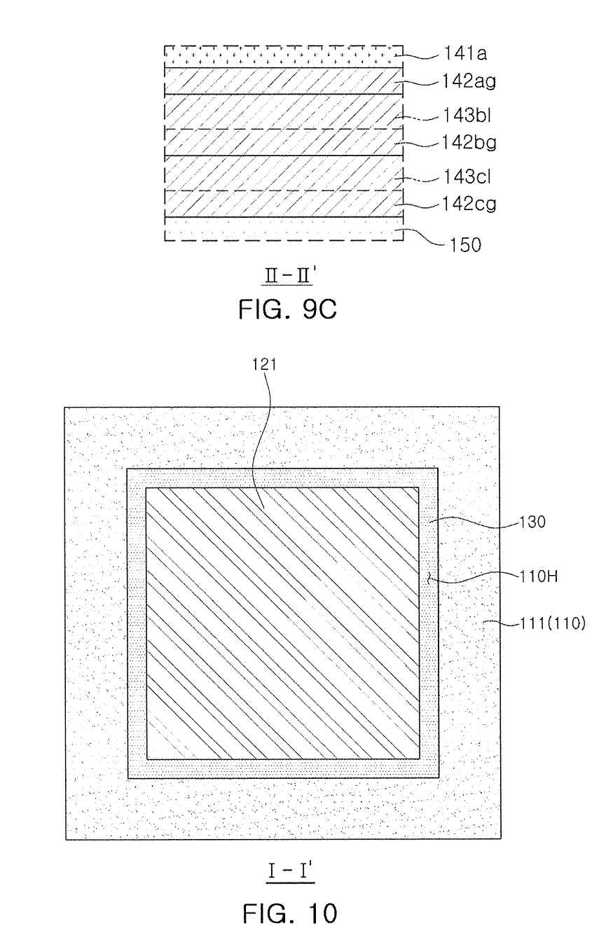

FIGS. 9A through 9C are schematic cross-sectional views illustrating an embodiment of a fan-out semiconductor package.

FIG. 9B illustrates an enlarged view of a region ‘A’ of FIG. 9A and FIG. 9C illustrates a cross section taken along line II-II′ of FIG. 9B.

FIG. 10 is a schematic plan view taken along line I-I′ of the fan-out semiconductor package of FIG. 9A.

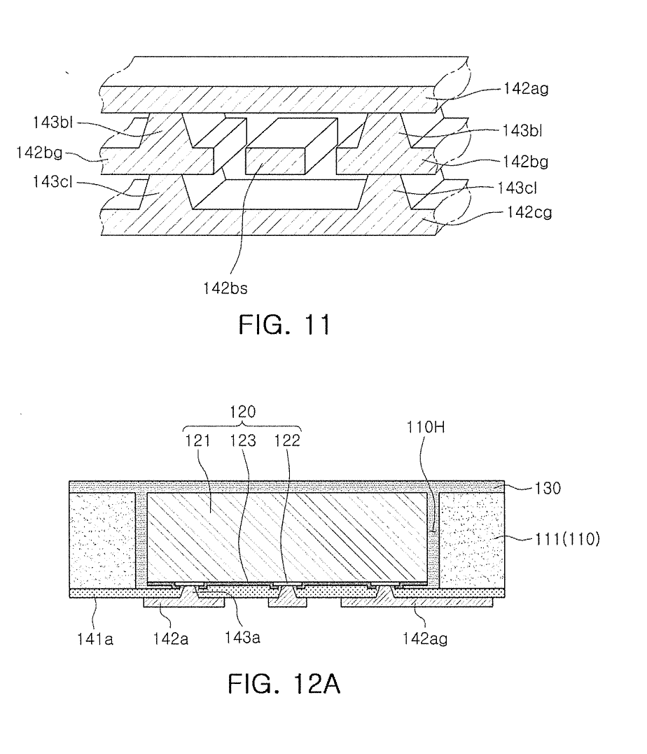

FIG. 11 is a schematic perspective view illustrating an embodiment of various signal patterns and ground patterns included in a connection member of the fan-out semiconductor package of FIG. 9A.

Referring to FIGS. 9A through 11, a fan-out semiconductor package 100A according to an exemplary embodiment in the present disclosure may include a core member 110 having a through-hole 110H, a semiconductor chip 120 disposed in the through-hole 110H of the core member 110 and having an active surface having connection pads 122 disposed thereon and an inactive surface opposing the active surface, an encapsulant 130 encapsulating at least portions of the core member 110 and the semiconductor chip 120, a connection member 140 disposed on the core member 110 and the active surface of the semiconductor chip 120, a passivation layer 150 disposed on the connection member 140, an underbump metal layer 160 disposed in openings 151 of the passivation layer 150, and electrical connection structures 170 disposed on the passivation layer 150 and connected to the underbump metal layer 160.

The connection member 140 may include a first insulating layer 141a disposed on the core member 110 and the active surface of the semiconductor chip 120, a first redistribution layer 142a disposed on the first insulating layer 141a, a first via 143a connecting the first redistribution layer 142a and the connection pads 122 of the semiconductor chip 120 to each other, a second insulating layer 141b disposed on the first insulating layer 141a, a second redistribution layer 142b disposed on the second insulating layer 141b, a second via 143b penetrating through the second insulating layer 141b and connecting the first and second redistribution layers 142a and 142b to each other, a third insulating layer 141c disposed on the second insulating layer 141b, a third redistribution layer 142c disposed on the third insulating layer 141c, and a third via 143c penetrating through the third insulating layer 141c and connecting the second and third redistribution layers 142b and 142c to each other.

The first redistribution layer 142a may include a first ground pattern 142ag, the second via 143b may include first line vias 143bl connected to the first ground pattern 142ag and having a line shape of a straight line extended in one direction, the second redistribution layer 142b may include a signal pattern 142bs and second ground patterns 142bg connected to the first line vias 143bl, the third via 143c may include second line vias 143cl connected to the second ground patterns 142bg and having a line shape of a straight line extended in one direction, and the third redistribution layer 142c may include third ground pattern 142cg connected to the second line vias 143cl.

The signal pattern 142bs may have the line shape of a straight line extending in one direction, and the first to third ground patterns 142ag, 142bg, and 142cg and the first and second line vias 143bl and 143cl may extend along the signal pattern 142bs and may be disposed to surround the entire of side surfaces of the signal pattern 142bs. Since the entire of the side surfaces of the signal pattern 142bs having a strip line shape of a straight line as described above is completely surrounded by the first to third ground patterns 142ag, 142bg, and 142cg and the first and second line vias 143bl and 143cl in the extending direction, it may be shielded from other redistribution layers 142a, 142b, and 142c, thereby significantly reducing interference such as coupling between the signal lines. In particular, since the first and second line vias 143bl and 143cl have the line shape of a straight line and are disposed on one straight line in a vertical direction while having the second ground pattern 142bg interposed therebetween, a shielding function may be improved as compared to a case in which vias having a general shape are disposed. Such structures of the signal pattern 142bs, the first to third ground patterns 142ag, 142bg, and 142cg, and the first and second line vias 143bl and 143cl may particularly be applied to a signal line which is sensitive to electrical or electromagnetic noise.

The respective components included in the fan-out semiconductor package 100A according to the exemplary embodiment will hereinafter be described in more detail.

The core member 110 may further improve rigidity of the fan-out semiconductor package 100A depending on certain materials, and serve to secure uniformity of a thickness of an encapsulant 130. When through-wirings, or the like, are formed in the core member 110, the fan-out semiconductor package 100A may be utilized as a package-on-package (POP) type package. The core member 110 may have the through-hole 110H. The semiconductor chip 120 may be disposed in the through-hole 110H to be spaced apart from the core member 110 by a predetermined distance. Side surfaces of the semiconductor chip 120 may be surrounded by the core member 110. However, such a form is only an example and may be variously modified to have other forms, and the core member 110 may perform another function depending on such a form. The core member 110 may be omitted, if necessary, but it may be more advantageous in securing board level reliability intended in the present disclosure that the fan-out semiconductor package 100A includes the core member 110.

The core member 110 may include an insulating layer 111. An insulating material may be used as the material of the insulating layer 111. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass fiber, a glass cloth or a glass fabric), for example, prepreg, Ajinomoto Build-up Film (ABF), FR-4, Bismaleimide Triazine (BT), or the like. Such a core member 110 may serve as a support member.

The semiconductor chip 120 may be an integrated circuit (IC) provided in an amount of several hundreds to several millions of elements or more integrated in a single chip. In this case, the IC may be, for example, a processor chip (more specifically, an application processor (AP)) such as a central processor (for example, a CPU), a graphic processor (for example, a GPU), a field programmable gate array (FPGA), a digital signal processor, a cryptographic processor, a microprocessor, a micro controller, or the like, but is not limited thereto. That is, the IC may be a logic chip such as an analog-to-digital converter, an application-specific IC (ASIC), or the like, or a memory chip such as a volatile memory (for example, a DRAM), a non-volatile memory (for example, a ROM and a flash memory), or the like. In addition, the above-mentioned elements may also be combined with each other and be disposed.

The semiconductor chip 120 may be formed on the basis of an active wafer. In this case, a base material of a body 121 may be silicon (Si), germanium (Ge), gallium arsenide (GaAs), or the like. Various circuits may be formed on the body 121. The connection pads 122 may electrically connect the semiconductor chip 120 to other components. A material of each of the connection pads 122 may be a conductive material such as aluminum (Al), or the like. A passivation layer 123 exposing the connection pads 122 may be formed on the body 121, and may be an oxide film, a nitride film, or the like, or a double layer of an oxide layer and a nitride layer. A lower surface of the connection pad 122 may have a step with respect to a lower surface of the encapsulant 130 through the passivation layer 123.

Resultantly, a phenomenon in which the encapsulant 130 bleeds into the lower surface of the connection pads 122 may be prevented to some extent. An insulating layer (not illustrated), and the like, may also be further disposed in other required positions. The semiconductor chip 120 may be a bare die, a redistribution layer (not illustrated) may be further formed on the active surface of the semiconductor chip 120, if necessary, and bumps (not illustrated), or the like, may be connected to the connection pads 122.

The encapsulant 130 may protect the core member 110, the semiconductor chip 120, and the like. An encapsulation form of the encapsulant 130 is not particularly limited, but may be a form in which the encapsulant 130 surrounds at least portions of the core member 110, the semiconductor chip 120, and the like. For example, the encapsulant 130 may cover the core member 110 and the inactive surface of the semiconductor chip 120, and fill spaces between walls of the through-hole 110H and the side surfaces of the semiconductor chip 120. In addition, the encapsulant 130 may also fill at least a portion of a space between the passivation layer 123 of the semiconductor chip 120 and the connection member 140. The encapsulant 130 may fill the through-hole 110H to thus serve as an adhesive and reduce buckling of the semiconductor chip 120 depending on certain materials.

A material of the encapsulant 130 is not particularly limited. For example, an insulating material may be used as the material of the encapsulant 150. In this case, the insulating material may be a thermosetting resin such as an epoxy resin, a thermoplastic resin such as a polyimide resin, a resin in which the thermosetting resin or the thermoplastic resin is mixed with an inorganic filler, or impregnated together with an inorganic filler in a core material such as a glass fiber (or a glass cloth or a glass fabric), for example, prepreg, Ajinomoto Build-up Film (ABF), FR-4, Bismaleimide Triazine (BT), or the like. Alternatively, a PID resin may also be used as the insulating material.

The connection member 140 may redistribute the connection pads 122 of the semiconductor chip 120. Several tens to several hundreds of connection pads 122 of the semiconductor chip 120 having various functions may be redistributed by the connection member 140, and may be physically or electrically externally connected through the electrical connection structures 170 depending on the functions. The connection member 140 may include a first insulating layer 141a disposed on the core member 110 and the active surface of the semiconductor chip 120, a first redistribution layer 142a disposed on the first insulating layer 141a, a first via 143a connecting the first redistribution layer 142a and the connection pads 122 of the semiconductor chip 120 to each other, a second insulating layer 141b disposed on the first insulating layer 141a, a second redistribution layer 142b disposed on the second insulating layer 141b, a second via 143b penetrating through the second insulating layer 141b and connecting the first and second redistribution layers 142a and 142b to each other, a third insulating layer 141c disposed on the second insulating layer 141b, a third redistribution layer 142c disposed on the third insulating layer 141c, and a third via 143c penetrating through the third insulating layer 141c and connecting the second and third redistribution layers 142b and 142c to each other. The first to third redistribution layers 142a, 142b, and 142c may be electrically connected to connection pads 122 of the semiconductor chip 120.

An insulating material may be used as a material of each of the insulating layers 141a, 141b, and 141c. In this case, a photosensitive insulating material such as a photo imagable dielectric (PID) resin may also be used as the insulating material in addition to the insulating material as described above. That is, the insulating layers 141a, 141b, and 141c may be photosensitive insulating layers. When the insulating layers 141a, 141b, and 141c has photosensitive properties, the insulating layers 141a, 141b, and 141c may be formed to have a smaller thickness, and fine pitches of the via 143a, 143b, and 143c may be achieved more easily. The insulating layers 141a, 141b, and 141c may be photosensitive insulating layers including an insulating resin and an inorganic filler. When the insulating layers 141a, 141b, and 141c are multiple layers, the materials of the insulating layers 141a, 141b, and 141c may be the same as each other, and may also be different from each other, if necessary. When the insulating layers 141a, 141b, and 141c are the multiple layers, the insulating layers 141a, 141b, and 141c may be integrated with each other depending on a process, such that a boundary therebetween may also not be apparent. A larger number of insulating layers than those illustrated in the drawing may be formed.

The redistribution layers 142a, 142b, and 142c may serve to substantially redistribute the connection pads 122. A material of each of the redistribution layers 142a, 142b, and 142c may be a conductive material such as copper (Cu), aluminum (Al), silver (Ag), tin (Sn), gold (Au), nickel (Ni), lead (Pb), titanium (Ti), or alloys thereof. The redistribution layers 142a, 142b, and 142c may perform various functions depending on designs of their corresponding layers. The redistribution layers 142a, 142b, and 142c may include a power (PWR) pattern in addition to ground (GND) patterns such as the first to third ground patterns 142ag, 142bg, and 142cg, and signal S patterns such as the signal pattern 142bs. Here, the signal S patterns may include various signals except for the ground (GND) patterns, the power (PWR) patterns, and the like, such as data signals, and the like. In addition, the redistribution layers 142a, 142b, and 142c may include via pad patterns, electrical connection structure pad patterns, and the like. A thickness of each of the redistribution layers 142a, 142b, and 142c may be about 0.5 μm to 15 μm.

The signal pattern 142bs may have a line shape of a straight line extending in one direction within the third insulating layer 141c. Each of the first and third ground patterns 142ag and 142cg may have a width greater than that of the signal pattern 142bs so as to extend while covering an upper surface and a lower surface of the signal pattern 142bs. The first and third ground patterns 142ag and 142cg may have a first width W1 extending from end portions of the first and second line vias 143bl and 143cl of one side of the signal pattern 142bs to end portions of the first and second line vias 143bl and 143cl of the other side of the signal pattern 142bs as a minimum width, and the first width W1 may be greater than a second width W2, which is a width of the signal pattern 142bs. The second ground patterns 142bg may be disposed to be spaced apart from both sides of the signal pattern 142bs by a predetermined distance. The spaced distance may be variously changed according to the exemplary embodiments and may be determined in consideration of a width and a thickness of the signal pattern 142bs, a layout of the redistribution layers 142a, 142b, and 142c around the signal pattern 142bs, a kind of applied signal, and the like. The first and third ground patterns 142ag and 142cg may have a width greater than that of the second ground patterns 142bg, but are not limited thereto. In addition, as another embodiment of the fan-out semiconductor package, the second ground patterns 142bg may also be changed to via pad patterns. Also in this case, however, since the second ground patterns 142bg are disposed along the first and second line vias 143bl and 143cl, the second ground patterns 142bg may have the line shape of a straight line.

The vias 143a, 143b, and 143c may electrically connect the redistribution layers 142a, 142b, and 142c, the connection pads 122, or the like, formed on different layers to each other, resulting in an electrical path in the fan-out semiconductor package 100A. A material of each of the vias 143a, 143b, and 143c may be a conductive material such as copper (Cu), aluminum (Al), silver (Ag), tin (Sn), gold (Au), nickel (Ni), lead (Pb), titanium (Ti), or alloys thereof. Each of the vias 143a, 143b, and 143c may be completely filled with the conductive material, or the conductive material may also be formed along a wall of each of the vias. In addition, each of the vias 143a, 143b, and 143c may have all of the shapes known in the related art, such as a tapered shape, a cylindrical shape, a shape having square or rectangular cross-section in a plan view and the like.

The first and second line vias 143bl and 143cl may be bar-shaped vias extending in one direction along the signal pattern 142bs (e.g. FIG. 11). The first and second line vias 143bl and 143cl may be disposed in a vertical direction while having the second ground pattern 142bg interposed therebetween on both sides of the signal pattern 142bs to thereby have a form of a dual layer via. That is, the first and second line vias 143bl and 143cl may be disposed to overlap with each other. In a case in which the signal pattern 142bs is bent on a plane, the first and second line vias 143bl and 143cl may also be disposed to be bent along the signal pattern 142bs. The first and second line vias 143bl and 143cl are illustrated in the drawings as having a lower surface wider than an upper surface (in other words, the coverage of the lower surface may be greater than the upper surface), but are not limited thereto.

The passivation layer 150 may protect the connection member 140 from external physical or chemical damage. The passivation layer 150 may have openings 151 exposing at least portions of the third redistribution layer 142c of the connection member 140. The number of openings 151 formed in the passivation layer 150 may be several tens to several thousands. A material of the passivation layer 150 is not particularly limited. For example, an insulating material may be used as the material of the passivation layer 150. In this case, the insulating material may be a thermosetting resin such as an epoxy resin, a thermoplastic resin such as a polyimide resin, a resin in which the thermosetting resin or the thermoplastic resin is mixed with an inorganic filler, or impregnated together with an inorganic filler in a core material such as a glass fiber (or a glass cloth or a glass fabric), for example, prepreg, Ajinomoto Build-up Film (ABF), FR-4, Bismaleimide Triazine (BT), or the like. Alternatively, a solder resist may also be used.

The underbump metal layer 160 may improve connection reliability of the electrical connection structures 170 to improve board level reliability of the fan-out semiconductor package 100A. The underbump metal layer 160 may be connected to the third redistribution layer 142c of the connection member 140 exposed through the openings 151 of the passivation layer 150. The underbump metal layer 160 may be formed in the openings 151 of the passivation layer 150 by a metallization method to deposit metal layers including aluminum, nickel, chromium, gold, germanium, copper, silver, titanium, tungsten, platinum, and tantalum, and selected metal alloys through filament, e-beam, flash, or inductive evaporation, or sputtering method on the wafer.

The electrical connection structures 170 may physically or electrically externally connect the fan-out semiconductor package 100A. For example, the fan-out semiconductor package 100A may be mounted on the main board of the electronic device through the electrical connection structures 170. Each of the electrical connection structures 170 may be formed of a conductive material, for example, a solder material such as tin-silver solder, tin-silver-copper (Sn—Ag-Cu or SAC) solder, tin-silver-copper-zinc (Sn—Ag—Cu—Zn) solder, and tin-silver-copper-manganese (Sn—Ag—Cu—Mn) solder, or the like. However, this is only an example, and a material of each of the electrical connection structures 170 is not limited thereto. Each of the electrical connection structures 170 may be a land, a ball, a pin, or the like. The electrical connection structures 170 may be formed as a multilayer or single layer structure. When the electrical connection structures 170 are formed as a multilayer structure, the electrical connection structures 170 may include a copper (Cu) pillar and a solder. When the electrical connection structures 170 are formed as a single layer structure, the electrical connection structures 170 may include a tin-silver solder or copper (Cu). However, this is only an example, and the electrical connection structures 170 are not limited thereto.

The number, an interval, a disposition form, and the like, of electrical connection structures 170 are not particularly limited, but may be sufficiently modified depending on design particulars by those skilled in the art. For example, the electrical connection structures 170 may be provided in an amount of several tens to several thousands according to the number of connection pads 122, or may be provided in an amount of several tens to several thousands or more or several tens to several thousands or less. When the electrical connection structures 170 are solder balls, the electrical connection structures 170 may cover side surfaces of the underbump metal layer 160 extending onto one surface of the passivation layer 150, and connection reliability may be more excellent.

At least one of the electrical connection structures 170 may be disposed in a fan-out region. The fan-out region is a region except for a region in which the semiconductor chip 120 is disposed. The fan-out package may have reliability greater than that of a fan-in package, may implement a plurality of I/O terminals, and may easily perform 3D interconnection In addition, as compared to a ball grid array (BGA) package, a land grid array (LGA) package, or the like, the fan-out package may be manufactured to have a small thickness, and may have price competitiveness.

Meanwhile, although not illustrated in the drawings, a metal thin film may be formed on the walls of the through-hole 110H, if necessary, in order to dissipate heat or block electromagnetic waves. In addition, a plurality of semiconductor chips 120 performing functions that are the same as or different from each other may be disposed in the through-hole 110H, if necessary. In addition, a separate passive component such as an inductor, a capacitor, or the like, may be disposed in the through-hole 110H, if necessary. In addition, a passive component, for example, a surface mounted technology (SMT) component including an inductor, a capacitor, or the like, may be disposed on a surface of the passivation layer 150, if necessary.

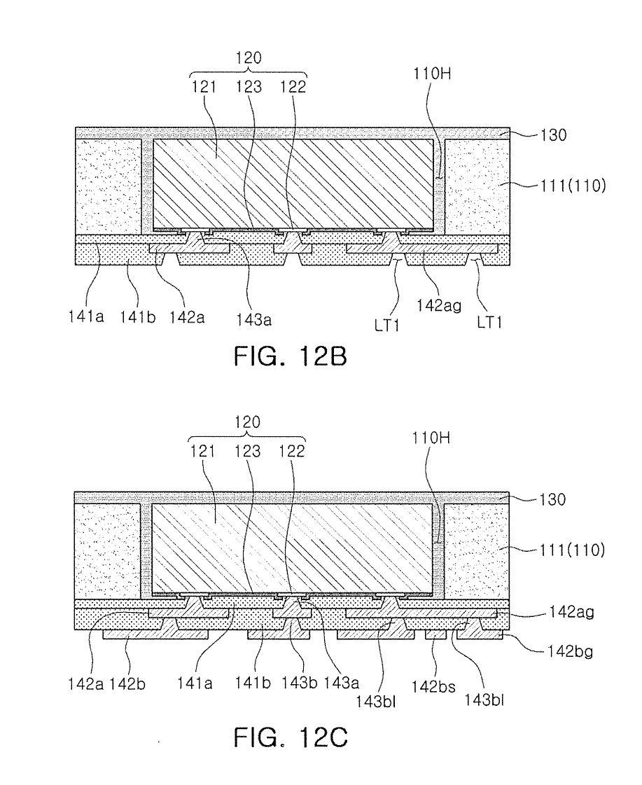

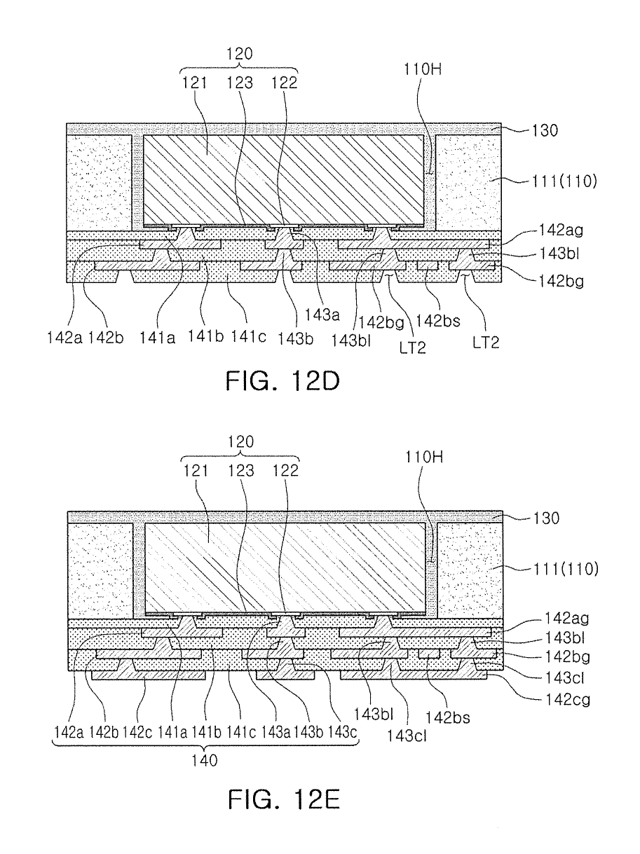

FIGS. 12A through 12E are schematic cross-sectional views illustrating an example of a processor for forming a connection member of the fan-out semiconductor package of FIG. 9A.

Referring to FIG. 12A, a first insulating layer 141a may be formed at a side in which the connection pad 122 of the semiconductor chip 120 is formed, a first via 143a penetrating through the first insulating layer 142a and connected to the connection pad 122 may be formed, and a first redistribution layer 142a connected to the first via 143a maybe formed on the first insulating layer 141a. The first redistribution layer 142a may include a first ground pattern 142ag. The first insulating layer 141a maybe formed by a lamination, a coating method, or the like, the first redistribution layer 142a may be formed by a plating process, and the first via 143a may be formed by the plating process together with the first redistribution layer 142a, but is not limited thereto. For example, the first via 143a may also be formed by a photolithography method such as ultra-violet (UV) photolithography, deep ultra-violet (DUV) photolithography, extreme ultra-violet (EUV) photolithography, and electron-beam (e-beam) photolithography, a method in which holes are formed by a mechanical drill and/or a laser drill and are filled with a conductive material using plating, or the like, depending on a material of the first insulating layer 141a.

Referring to FIG. 12B, a second insulating layer 141b covering the first redistribution layer 142a may be formed on the first insulating layer 141a, and via holes exposing the first redistribution layer 142a may be formed by patterning the second insulating layer 141b. Each of the via holes may have a circular cross section. During the formation of the via holes, first line trenches LT1 exposing the first ground pattern 142ag and having a line shape of a straight line may be formed together with the via holes. The second insulating layer 141b may be formed by a lamination, a coating method, or the like, and the via holes and the first line trenches LT1 may be formed by a photolithography method such as ultra-violet (UV) photolithography, deep ultra-violet (DUV) photolithography, extreme ultra-violet (EUV) photolithography, and electron-beam (e-beam) photolithography, a mechanical drill and/or a laser drill, or the like, but is not limited thereto.

Referring to FIG. 12C, a second via 143b filling the first line trenches LT1 and the via holes and connected to the first redistribution layer 142a may be formed, and a second redistribution layer 142b connected to the second via 143b may be formed on the second insulating layer 141b. The second via 143b may include first line vias 143bl, and the second redistribution layer 142b may include a signal pattern 142bs and second ground patterns 142bg connected to the first line vias 143bl. The signal pattern 142bs and the second ground patterns 142bg may have a line shape of a straight line. The second via 143b and the second redistribution layer 142b may be formed by a plating process, or the like.

Referring to FIG. 12D, a third insulating layer 141c covering the second redistribution layer 142b may be formed on the second insulating layer 141b, and via holes exposing the second redistribution layer 142b may be formed by patterning the third insulating layer 141c. Each of the via holes may have a circular cross section. During the formation of the via holes, second line trenches LT2 exposing the second ground pattern 142bg and having a line shape of a straight line may be formed together with the via holes. The third insulating layer 141c may be formed by a lamination, a coating method, or the like, and the via holes and the second line trenches LT2 may be formed by a photolithography method such as ultra-violet (UV) photolithography, deep ultra-violet (DUV) photolithography, extreme ultra-violet (EUV) photolithography, and electron-beam (e-beam) photolithography, a mechanical drill such as mechanical punching and/or a laser drill, electron beam machining, or the like.

Referring to FIG. 12E, a third via 143c filling the second line trenches LT2 and the via holes and connected to the second redistribution layer 142b may be formed, and a third redistribution layer 142c connected to the third via 143c may be formed on the third insulating layer 141c. The third via 143c may include second line vias 143cl, and the third redistribution layer 142c may include a third ground pattern 142cg connected to the second line vias 143cl. The third via 143c and the third redistribution layer 142c may be formed by a plating process, or the like.

Next, referring to FIG. 9, a passivation layer 150 covering the third redistribution layer 142c may be formed, openings exposing at least a portion of the third redistribution layer 142c may be formed in the passivation layer 150, and an underbump metal layer 160 may be formed on the openings 151. The passivation layer 150 may also be formed by a method of laminating a precursor of the passivation layer 150 and then hardening the precursor, a method of applying a material for forming the passivation layer 150 and then hardening the material, or the like. The underbump metal layer 160 may be formed by a metallization method to deposit metal layers including aluminum, nickel, chromium, gold, germanium, copper, silver, titanium, tungsten, platinum, and tantalum, and selected metal alloys through filament, e-beam, flash, or inductive evaporation, or sputtering method on the wafer.

Electrical connection structures 170 may be formed on the underbump metal layer 160, if necessary. A method of forming the electrical connection structures 170 is not particularly limited. That is, the electrical connection structures 170 may be formed by the method well-known in the related art depending on their structures or forms. The electrical connection structures 170 may be fixed by reflow, and portions of the electrical connection structures 170 may be embedded in the passivation layer 150 in order to enhance fixing force, and the remaining portions of the electrical connection structures 170 may be externally exposed, such that reliability may be improved. In some cases, only the underbump metal layer 160 may be formed, if necessary, by a separate process by a client purchasing the fan-out semiconductor package 100A.

Meanwhile, a series of processes may be processes of preparing a core member 110 having a large size, manufacturing a plurality of fan-out semiconductor packages 100A through the above-mentioned process, and then singulating the plurality of fan-out semiconductor packages into an individual fan-out semiconductor package 100A through a sawing process in order to facilitate mass production. In this case, productivity may be excellent.

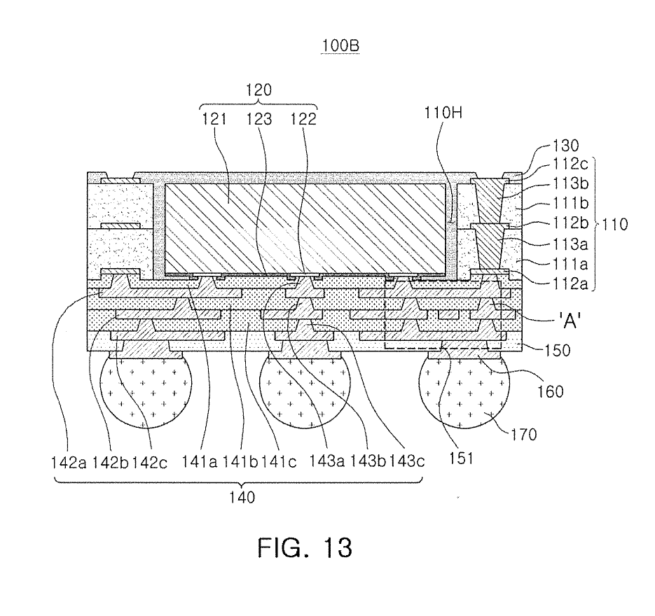

FIG. 13 is a schematic cross-sectional view illustrating another example of a fan-out semiconductor package.

Referring to FIG. 13, in a fan-out semiconductor package 100B according to another exemplary embodiment in the present disclosure, a core member 110 may include a first insulating layer 111a in contact with a connection member 140, a first wiring layer 112a in contact with the connection member 140 and embedded in the first insulating layer 111a, a second wiring layer 112b disposed on the other surface of the first insulating layer 111a opposing one surface of the first insulating layer 111a in which the first wiring layer 112a is embedded, a second insulating layer 111b disposed on the first insulating layer 111a and covering the second wiring layer 112b, and a third wiring layer 112c disposed on the second insulating layer 111b. The first to third wiring layers 112a, 112b, and 112c may be electrically connected to connection pads 122. The first and second wiring layers 112a and 112b and the second and third wiring layers 112b and. 112c may be electrically connected to each other through first and second vias 113a and 113b penetrating through the first and second insulating layers 111a and 111b, respectively.

When the first wiring layer 112a is embedded in the first insulating layer 111a, a step generated due to a thickness of the first wiring layer 112a may be significantly reduced, and an insulating distance of the connection member 140 may thus become constant. That is, a difference between a distance from a first redistribution layer 142a of the connection member 140 to a lower surface of the first insulating layer 111a and a distance from the first redistribution layer 142a of the connection member 140 to the connection pad 122 of a semiconductor chip 120 may be smaller than a thickness of the first wiring layer 112a. Therefore, a high density wiring design of the connection member 140 may be easy.

The lower surface of the first wiring layer 112a of the core member 110 may be disposed on a level above a lower surface of the connection pad 122 of a semiconductor chip 120. In addition, a distance between a first redistribution layer 142a of the connection member 140 and the first redistribution layer 112a of the core member 110 may be greater than that between the first redistribution layer 142a of the connection member 140 and the connection pad 122 of the semiconductor chip 120.

The reason is that the first wiring layer 112a maybe recessed into the first insulating layer 111a. As described above, when the first wiring layer 112a is recessed into the first insulating layer 111a, such that the lower surface of the first insulating layer 111a and the lower surface of the first wiring layer 112a have a step therebetween, a phenomenon in which a material of the encapsulant 130 bleeds to pollute the first wiring layer 112a may be prevented. The second redistribution layer 112b of the core member 110 may be disposed between an active surface and an inactive surface of the semiconductor chip 120. The core member 110 may be formed at a thickness corresponding to that of the semiconductor chip 120. Therefore, the second wiring layer 112b formed in the core member 110 may be disposed on a level between the active surface and the inactive surface of the semiconductor chip 120.

In FIG. 13, though the connection member 140 is relatively enlarged for explanation of the connection member 140, thicknesses of the wiring layers 112a, 112b, and 112c of the core member 110 may be greater than those of the redistribution layers 142a, 142b, and 142c of the connection member 140. Since the core member 110 may have a thickness equal to or greater than that of the semiconductor chip 120, the wiring layers 112a, 112b, and 112c may be formed at larger sizes depending on a scale of the core member 110. On the other hand, the redistribution layers 142a, 142b, and 142c of the connection member 140 may be formed at sizes relatively smaller than those of the wiring layers 112a, 112b, and 112c for thinness.

A material of each of the insulating layers 111a and 111b is not particularly limited. For example, an insulating material may be used as the material of the insulating layers 111a and 111b. In this case, the insulating material may be a thermosetting resin such as an epoxy resin, a thermoplastic resin such as a polyimide resin, a resin in which the thermosetting resin or the thermoplastic resin is mixed with an inorganic filler, or impregnated together with an inorganic filler in a core material such as a glass fiber (or a glass cloth or a glass fabric), for example, prepreg, Ajinomoto Build-up Film (ABF), FR-4, Bismaleimide Triazine (BT), or the like. Alternatively, a PID resin may also be used as the insulating material.

The wiring layers 112a, 112b, and 112c may serve to redistribute the connection pads 122 of the semiconductor chip 120. A material of each of the wiring layers 112a, 112b, and 112c may be a conductive material such as copper (Cu), aluminum (Al), silver (Ag), tin (Sn), gold (Au), nickel (Ni), lead (Pb), titanium (Ti), or alloys thereof. The wiring layers 112a, 112b, and 112c may perform various functions depending on designs of their corresponding layers. For example, the wiring layers 112a, 112b, and 112c may include ground (GND) patterns, power (PWR) patterns, signal (S) patterns, and the like. Here, the signal (S) patterns may include various signals except for the ground (GND) patterns, the power (PWR) patterns, and the like, such as data signals, and the like. In addition, the wiring layers 112a, 112b, and 112c may include via pads, wire pads, connection terminal pads, and the like.

The vias 113a and 113b may electrically connect the wiring layers 112a, 112b, and 112c formed on different layers to each other, resulting in an electrical path in the core member 110. A material of each of the vias 113a and 113b may be a conductive material. Each of the vias 113a and 113b may be completely filled with a conductive material, or a conductive material may also be formed along a wall of each of via holes. In addition, each of the vias 113a and 113b may have all of the shapes known in the related art, such as a tapered shape, a cylindrical shape, and the like. When holes for the first vias 113a are formed, some of the pads of the first wiring layer 112a may serve as a stopper, and it may thus be advantageous in a process that each of the first vias 113a has the tapered shape of which a width of an upper surface is greater than that of a lower surface. In this case, the first vias 113a may be integrated with pad patterns of the second wiring layer 112b. In addition, when holes for the second vias 113b are formed, some of the pads of the second wiring layer 112b may serve as a stopper, and it may thus be advantageous in a process that each of the second vias 113b has the tapered shape of which a width of an upper surface is greater than that of a lower surface. In this case, the second vias 113b may be integrated with pad patterns of the third wiring layer 112c.

The contents about other configurations, for example, signal patterns and ground patterns of a region ‘A’ described with reference to FIGS. 9A through 11 may also be applied to the fan-out semiconductor package 1008 according to another exemplary embodiment, and a detailed description thereof is substantially the same as that described in the fan-out semiconductor package 100A described above. Therefore, the detailed description thereof will be omitted.

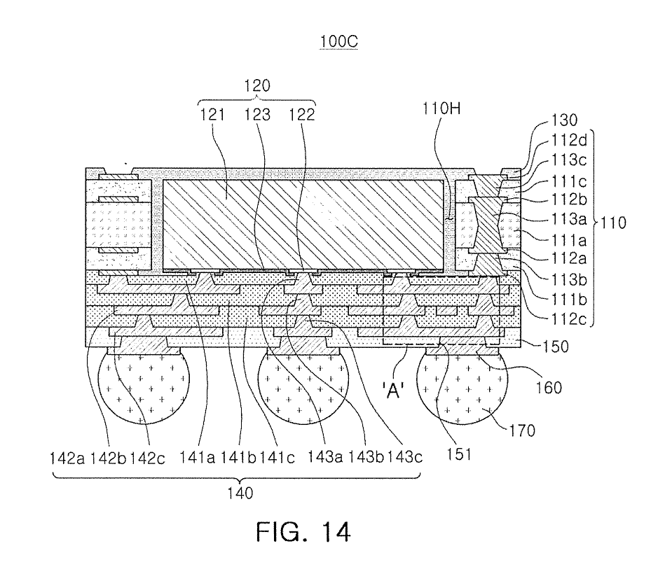

FIG. 14 is a schematic cross-sectional view illustrating another example of a fan-out semiconductor package.

Referring to FIG. 14, in a fan-out semiconductor package 100C according to another exemplary embodiment in the present disclosure, a core member 110 may include a first insulating layer 111a, a first wiring layer 112a and a second wiring layer 112b disposed on opposite surfaces of the first insulating layer 111a, respectively, a second insulating layer 111b disposed on the first insulating layer 111a and covering the first wiring layer 112a, a third wiring layer 112c disposed on the second insulating layer 111b, a third insulating layer 111c disposed on the first insulating layer 111a and covering the second wiring layer 112b, and a fourth wiring layer 112d disposed on the third insulating layer 111c. The first to fourth wiring layers 112a, 112b, 112c, and 112d may be electrically connected to connection pads 122. Since the core member 110 may include a larger number of wiring layers 112a, 112b, 112c, and 112d, a connection member 140 maybe further simplified. Therefore, a decrease in a yield depending on a defect occurring in a process of forming the connection member 140 may be suppressed. Meanwhile, the first to fourth wiring layers 112a, 112b, 112c, and 112d may be electrically connected to each other through first to third vias 113a, 113b, and 113c each penetrating through the first to third insulating layers 111a, 111b, and 111c.

The first insulating layer 111a may have a thickness greater than those of the second insulating layer 111b and the third insulating layer 111c. The first insulating layer 111a may be basically relatively thick in order to maintain rigidity, and the second insulating layer 111b and the third insulating layer 111c may be introduced in order to form a larger number of wiring layers 112c and 112d. The first insulating layer 111a may include an insulating material different from those of the second insulating layer 111b and the third insulating layer 111c. For example, the first insulating layer 111a may be, for example, prepreg including a core material, a filler, and an insulating resin, and the second insulating layer 111b and the third insulating layer 111c may be an ABF or a PID film including a filler and an insulating resin. However, the materials of the first insulating layer 111a and the second and third insulating layers 111b and 111c are not limited thereto. Similarly, the first vias 113a penetrating through the first insulating layer 111a may have a diameter greater than those of second vias 113b and third vias 113c each penetrating through the second insulating layer 111b and the third insulating layer 111c.

A lower surface of the third wiring layer 112c of the core member 110 may be disposed on a level below a lower surface of the connection pad 122 of a semiconductor chip 120. In addition, a distance between a first redistribution layer 142a of the connection member 140 and the third wiring layer 112c of the core member 110 may be smaller than that between the first redistribution layer 142a of the connection member 140 and the connection pad 122 of the semiconductor chip 120. The reason is that the third wiring layer 112c may be disposed in a protruding form on the second insulating layer 111b, resulting in being in contact with the connection member 140. The first wiring layer 112a and the second wiring layer 112b of the core member 110 may be disposed between an active surface and an inactive surface of the semiconductor chip 120. The core member 110 may be formed at a thickness corresponding to that of the semiconductor chip 120. Therefore, the first wiring layer 112a and the second wiring layer 112b formed in the core member 110 may be disposed on a level between the active surface and the inactive surface of the semiconductor chip 120.

In FIG. 14, though the connection member 140 is relatively enlarged for explanation of the connection member 140, thicknesses of the wiring layers 112a, 112b, 112c, and 112d of the core member 110 may be greater than those of the redistribution layers 142a, 142b, and 142c of the connection member 140. Since the core member 110 may have a thickness equal to or greater than that of the semiconductor chip 120, the wiring layers 112a, 112b, 112c, and 112d may also be formed at larger sizes. On the other hand, the redistribution layers 142a, 142b, and 142c of the connection member 140 maybe formed at relatively small sizes for thinness.

The contents about other configurations, for example, signal patterns and ground patterns of a region ‘A’ described with reference to FIGS. 9A through 11 may also be applied to the fan-out semiconductor package 100C according to another exemplary embodiment, and a detailed description thereof is substantially the same as that described in the fan-out semiconductor package 100A described above. Therefore, the detailed description thereof will be omitted.

Herein, a lower side, a lower portion, a lower surface, and the like, are used to refer to a direction toward a mounting surface of the fan-out semiconductor package in relation to cross sections of the drawings, while an upper side, an upper portion, an upper surface, and the like, are used to refer to an opposite direction to the direction. However, these directions are defined for convenience of explanation, and the claims are not particularly limited by the directions defined as described above.

The meaning of a “connection” of a component to another component in the description includes an indirect connection through an adhesive layer as well as a direct connection between two components. In addition, “electrically connected” conceptually includes a physical connection and a physical disconnection. It can be understood that when an element is referred to with “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The term “an exemplary embodiment” used herein does not refer to the same exemplary embodiment, and is provided to emphasize a particular feature or characteristic different from that of another exemplary embodiment. However, exemplary embodiments provided herein are considered to be able to be implemented by being combined in whole or in part one with another. For example, one element described in a particular exemplary embodiment, even if it is not described in another exemplary embodiment, may be understood as a description related to another exemplary embodiment, unless an opposite or contradictory description is provided therein.

Terms used herein are used only in order to describe an exemplary embodiment rather than limiting the present disclosure. In this case, singular forms include plural forms unless interpreted otherwise in context.

As set forth above, according to the exemplary embodiments in the present disclosure, in the connection member for redistributing the connection pads of the semiconductor chip, the semiconductor package that enhances the electrical shielding between the adjacent signal lines to remove the mutual interference may be provided.

While exemplary embodiments have been shown and described above, it will be apparent to those skilled in the art that modifications and variations could be made without departing from the scope of the present invention as defined by the appended claims.

1. A semiconductor package comprising:
a semiconductor chip having an active surface having connection pads disposed thereon and an inactive surface opposing the active surface;
an encapsulant encapsulating at least a portion of the semiconductor chip; and
a connection member including
an insulating layer disposed on the active surface of the semiconductor chip and the encapsulant,
a signal pattern disposed in the insulating layer,
first ground patterns disposed to be spaced apart from the signal pattern on both sides of the signal pattern,
second ground patterns disposed to be spaced apart from an upper portion and a lower portion of the signal pattern, and
line vias connecting the first ground patterns and the second ground patterns to each other and having a line shape, and
the line vias are stacked in a thickness direction of the semiconductor chip while having respective first ground patterns interposed therebetween.

2. (canceled)

3. The semiconductor package of claim 1, wherein the signal pattern has a line shape of a straight line extending in one direction, and
the first and second ground patterns and the line vias extend along the signal pattern.

4. The semiconductor package of claim 3, wherein all of the surfaces of the signal pattern parallel to the extended direction are surrounded by the first and second ground patterns and the line vias.

5. The semiconductor package of claim 1, wherein the second ground patterns have widths greater than a width of the signal pattern.

6. The semiconductor package of claim 1, wherein the second ground patterns have widths greater than widths of the first ground patterns.

7. The semiconductor package of claim 1, wherein the insulating layer includes:
a first insulating layer disposed on the active surface of the semiconductor chip,
a second insulating layer disposed on the first insulating layer so as to cover the second ground pattern of one side of the signal pattern, and
a third insulating layer disposed on the second insulating layer so as to cover the signal pattern and the first ground patterns.

8. The semiconductor package of claim 7, wherein respective line vias penetrates through the second and third insulating layers.

9. The semiconductor package of claim 7, further comprising a passivation layer disposed on the third insulating layer so as to cover the second ground pattern of the other side of the signal pattern,.
wherein the passivation layer includes openings, in which electrical connection structures, electrically connected to a lowermost one of redistribution layers of the connection member, are disposed.

10. The semiconductor package of claim 1, further comprising a core member having a through-hole,
wherein the semiconductor chip is disposed in the through-hole of the core member,
the encapsulant fills at least portions of the through-hole and covers an upper surface of the core member, and
a lower surface of the core member, opposing the upper surface of the core member, faces the connection member.

11. The semiconductor package of claim 10, wherein the core member includes a first core insulating layer, a first wiring layer in contact with the connection member and embedded in the first core insulating layer, and a second wiring layer disposed on the other surface of the first core insulating layer opposing one surface of the first core insulating layer in which the first wiring layer is embedded, and
the first and second wiring layers are electrically connected to the connection pads.

12. The semiconductor package of claim 11, wherein the core member further includes a second core insulating layer disposed on the first core insulating layer and covering the second wiring layer, and a third wiring layer disposed on the second core insulating layer, and
the third wiring layer is electrically connected to the connection pads.

13. The semiconductor package of claim 10, wherein the core member includes a first core insulating layer, and first and second wiring layers disposed on opposite surfaces of the first core insulating layer, and
the first and second wiring layers are electrically connected to the connection pads.

14. The semiconductor package of claim 13, wherein the core member further includes a second core insulating layer disposed on the first core insulating layer and covering the first wiring layer, and a third wiring layer disposed on the second core insulating layer, and
the third wiring layer is electrically connected to the connection pads.

15. A semiconductor package comprising:
a semiconductor chip having an active surface having connection pads disposed thereon and an inactive surface opposing the active surface;
an encapsulant encapsulating at least a portion of the semiconductor chip; and
a connection member disposed on the active surface of the semiconductor chip and the encapsulant, and including a signal pattern having a line shape, ground patterns disposed to be spaced apart from the signal pattern, and line vias connecting the ground patterns to each other and having a line shape,
wherein all of the side surfaces of the signal pattern in an extending direction of the signal pattern are surrounded by ground patterns and the line vias,
a width of one of the line vias in a cross-section of the one of the line vias decreases along a thickness direction of the semiconductor chip from the connection member to the semiconductor chip, the cross-section being intersected by a lengthwise direction of the one of the line vias along which the one of the line vias extends.

16. The semiconductor package of claim 15, wherein the connection member includes:
a first insulating layer disposed on the active surface of the semiconductor chip;
a first via penetrating through the first insulating layer and connected to the connection pad;
a first redistribution layer disposed on the first insulating layer and including a first ground pattern;
a second insulating layer disposed on the first insulating layer and covering the first redistribution layer;
a second via penetrating through the second insulating layer, connected to the first redistribution layer, and including first line vias connected to the first ground pattern; a second redistribution layer disposed on the second insulating layer, and including the signal pattern and second ground patterns disposed to be spaced apart from the signal pattern and connected to the first line vias;
a third insulating layer disposed on the second insulating layer and covering the second redistribution layer;
a third via penetrating through the third insulating layer and connected to the second redistribution layer, and including second line vias connected to the second ground patterns; and a third redistribution layer disposed on the third insulating layer and including a third ground pattern connected to the second line vias.

17. A semiconductor package comprising:
a semiconductor chip having an active surface having connection pads disposed thereon and an inactive surface opposing the active surface;
an encapsulant encapsulating at least a portion of the semiconductor chip; and
a connection member including
an insulating layer disposed on the active surface of the semiconductor chip and the encapsulant,
a signal pattern disposed in the insulating layer,
first ground patterns disposed to be spaced apart from the signal pattern on both sides of the signal pattern,
second ground patterns disposed to be spaced apart from an upper portion and a lower portion of the signal pattern,
line vias parallel to each other and connecting the first ground patterns and the second ground patterns to each other and having a line shape extending in a lengthwise direction of the signal pattern,
a width of one of the line vias in a cross-section of the one of the line vias decreases along a thickness direction of the semiconductor chip from the connection member to the semiconductor chip, the cross-section being intersected by a lengthwise direction of the one of the line vias along which the one of the line vias extends.

18. The semiconductor package of claim 17, wherein the line vias are stacked in a thickness direction of the semiconductor chip while having respective first ground patterns interposed therebetween.

19. The semiconductor package of claim 17, wherein the signal pattern has a line shape of a straight line extending in one direction, and
the first and second ground patterns and the line vias extend along the signal pattern.

20. The semiconductor package of claim 19, wherein all of the surfaces of the signal pattern parallel to the extended direction are surrounded by the first and second ground patterns and the line vias.

21. The semiconductor package of claim 1, wherein a width of one of the line vias in a cross-section of the one of the line vias decreases along the thickness direction of the semiconductor chip from the connection member to the semiconductor chip, the cross-section being intersected by a lengthwise direction of the one of the line vias along which the one of the line vias extends.

22. The semiconductor package of claim 1, wherein the insulating layer of the connection member is in physical contact with the semiconductor chip.
